(19) United States
(12) Patent Application Publication
(10) Pub. No.: US 2018/0203136 A1
(43) Pub. Date: Jul. 19, 2018

(54) LOW NOISE IMAGING DETECTOR AND A METHOD FOR MANUFACTURING THE SAME

(71) Applicant: General Electric Company, Schenectady, NY (US)

(72) Inventors: Jie Jerry Liu, Niskayuna, NY (US); Kwang Hyup An, Rexford, NY (US); Douglas Albagli, Clifton park, NY (US)

(21) Appl. No.: 15/405,961

(22) Filed: Jan. 13, 2017

(51) Int. Cl. G01T 1/24; H01L 51/44; H01L 27/30; G01N 23/04

(52) U.S. Cl. CPC G01T 1/244; H01L 51/44; G01N 23/04; H01L 27/308; G01T 1/241; H01L 27/307

(57) ABSTRACT

An imaging detector, an imaging system having the imaging detector, and a method for manufacturing the imaging detector are disclosed. The imaging detector includes a substrate, a plurality of thin film transistors (TFTs) disposed on the substrate, a data line disposed on the substrate electrically coupled to at least two TFTs of the plurality of TFTs, a pixelated bottom electrode disposed on the substrate and laterally offset from the data line, a continuous organic photodiode layer, and a continuous top electrode layer overlaid on the continuous organic photodiode layer. The continuous organic photodiode layer is at least partially overlaid on the plurality of TFTs, the data line, and the pixelated bottom electrode and includes a first portion overlaid on the data line and a second portion overlaid on the pixelated bottom electrode. First portion is thicker than the second portion.

### BACKGROUND

Embodiments of the invention relate generally to imaging detectors and, more particularly, to low noise imaging detectors having a continuous organic photodiode layer and method for manufacturing an imaging detector.

Imaging detectors, such as, for example, digital X-ray detectors are fabricated using continuous photodiodes to reduce manufacturing cost, reduce weight, and increase portability. Imaging detectors having continuous photodiodes have increased fill factor and potentially higher quantum efficiency. One drawback of imaging detectors having continuous photodiodes and a continuous electrode layer on the continuous photodiodes is that the structure of continuous photodiode and electrode can increase electronic noise. An additional data line capacitance of the data line(s) increases generated electronic noise. Therefore, it is desirable to have an enhanced imaging detector.

### BRIEF DESCRIPTION

In one aspect, an imaging detector is disclosed. The imaging detector includes a substrate, a plurality of thin film transistors (TFTs) disposed on the substrate, a data line disposed on the substrate electrically coupled to at least two TFTs of the plurality of TFTs, a pixelated bottom electrode disposed on the substrate and laterally offset from the data line, a continuous organic photodiode layer, and a continuous top electrode. The continuous organic photodiode layer is at least partially overlaid on the plurality of TFTs, the data line, and the pixelated bottom electrode. The continuous organic photodiode layer includes a first portion overlaid on the data line and a second portion overlaid on the pixelated bottom electrode. A thickness of the first portion is greater than a thickness of the second portion. The continuous top electrode layer is disposed such that it is overlaid on the continuous organic photodiode layer.

In another aspect, an imaging system is disclosed. The imaging system includes a source configured to generate a plurality of electromagnetic radiations, a collimator disposed aligned with the source and configured to collimate the plurality of electromagnetic radiations, and an imaging detector disposed aligned with the source and collimator and configured to detect image of an object through which the collimated electromagnetic radiation passed through. The imaging detector includes a substrate, a plurality of TFTs disposed on the substrate, a data line disposed on the substrate electrically coupled to at least two TFTs of the plurality of TFTs, a pixelated bottom electrode disposed on the substrate and laterally offset from the data line, a continuous organic photodiode layer, and a continuous top electrode. The continuous organic photodiode layer is at least partially overlaid on the plurality of TFTs, the data line, and the pixelated bottom electrode. The continuous organic photodiode layer includes a first portion overlaid on the data line and a second portion overlaid on the pixelated bottom electrode. A thickness of the first portion is greater than a thickness of the second portion. The continuous top electrode layer is disposed such that it is overlaid on the continuous organic photodiode layer.

In yet another aspect, a method for manufacturing an imaging detector is disclosed. The method includes disposing a plurality of TFTs on a substrate, disposing a data line on the substrate and electrically coupling the data line and at least two TFTs of the plurality of TFTs, disposing a pixelated bottom electrode on the substrate, laterally offset from the data line, disposing a continuous organic photodiode layer, and disposing a continuous top electrode layer overlaying the continuous organic photodiode layer. The continuous organic photodiode layer is disposed such that the continuous organic photodiode layer at least partially overlays the plurality of TFTs, the data line, and the pixelated bottom electrode. Further, the continuous organic photodiode layer includes a first portion overlaying the data line and a second portion overlaying the pixelated bottom electrode such that a thickness of the first portion is greater than a thickness of the second portion.

### DRAWINGS

Various features, aspects, and advantages of the present disclosure will become better understood when the following detailed description is read with reference to the accompanying drawings in which like characters represent like parts throughout the drawings. Unless otherwise indicated, the drawings provided herein are meant to illustrate only key features of the disclosure. These key features are believed to be applicable in a wide variety of systems which comprises one or more embodiments of the disclosure. As such, the drawings are not meant to include all conventional features known by those of ordinary skill in the art to be required for practicing the disclosure.

FIG. 1 illustrates block diagram of an exemplary imaging system including an imaging detector in accordance with an exemplary embodiment.

FIG. 2 is a side cross-sectional view of an imaging detector in accordance with some embodiments of the present invention.

FIG. 3 is a side cross-sectional view of an imaging detector in accordance with some embodiments of the present invention.

FIG. 4 is a lateral cross sectional view of an imaging detector, in accordance with some embodiments of the present invention.

FIG. 5 is a lateral cross sectional view of the imaging detector in accordance with some embodiments of the present invention.

FIG. 6 is a side cross-sectional view of an imaging detector in accordance with some embodiments of the present invention.

FIG. 7 is a side cross-sectional view of an imaging detector in accordance with another embodiment of the present invention.

FIG. 8 is a flowchart of an exemplary process for manufacturing an imaging detector in accordance with some embodiments of the present invention.

### DETAILED DESCRIPTION

Embodiments of the present invention disclose imaging detectors, such as for example, X-ray detectors, fabricated using a continuous organic photodiode layer, wherein the continuous organic photodiode layer is disposed overlaying at least a portion of one or more data lines associated with a plurality of thin film transistors (TFTs) disposed at pixel areas of the imaging detector. Speed of the imaging detector is enhanced and electronic noise of the imaging detector is reduced by controlling a data line capacitance generated by the continuous organic photodiode layer.

An increase in data line capacitance in an imaging detector can be attributed, at least in part, to direct coupling of the data line(s) to an un-patterned electrode of a continuous organic photodiode layer. An added loading caused by such a coupling can increase electronic noise of data conversion electronic unit of the imaging detector. Additionally, load capacitance can affect the data readout speed of the data conversion electronic unit.

Embodiments of the present invention disclose controlling capacitance of data lines of an exemplary imaging detector to improve data readout speed and reduce electronic noise compared to convention imaging detectors. In accordance with the embodiments of the present invention, load capacitance of the data lines is controlled by controlling a parasitic capacitance between the data lines and an electrode of the continuous organic photodiode layer of the imaging detector by specifying a spatial offset of the electrode to the data lines.

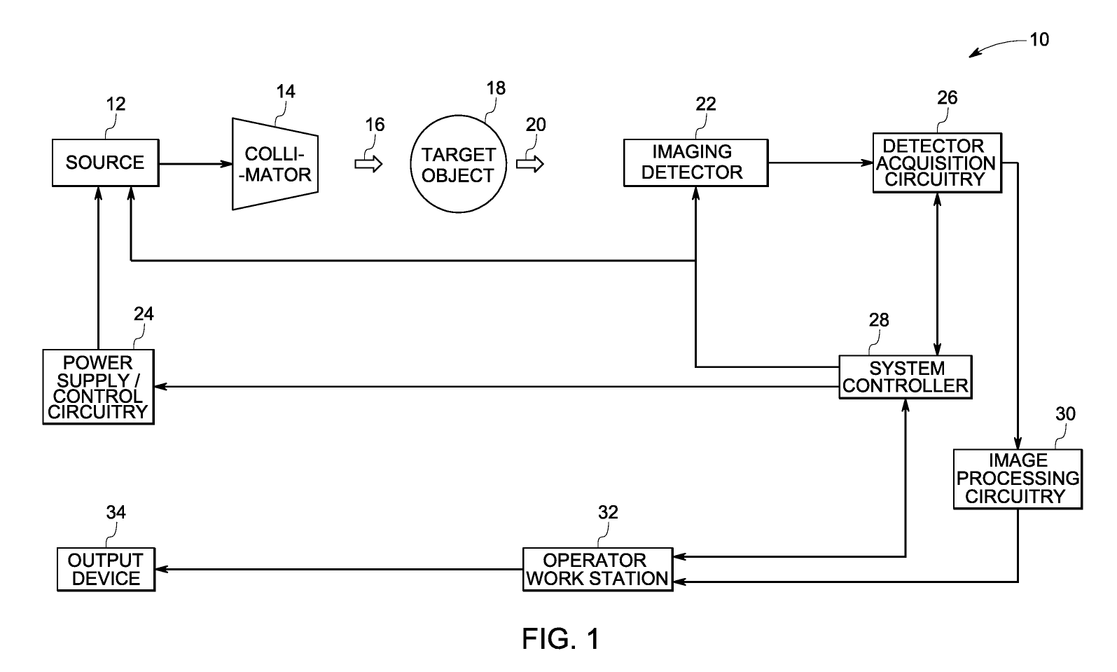

FIG. 1 illustrates a block diagram of an imaging system 10 in accordance with an exemplary embodiment of the present invention. The system 10 includes a source 12, a collimator 14, and an imaging detector. The source 12 is configured to generate a plurality of electromagnetic radiations 16. In some embodiments, the source 12 is a low-energy source employed for low energy imaging techniques, such as fluoroscopic techniques or the like. The collimator 14 is disposed aligned with the source 12 and configured to collimate the plurality of electromagnetic radiations 16. The collimator 14 is used to direct the plurality of electromagnetic radiations 16 emitted by the source 12 to a target object 18, such as, for example, a human patient. Some of the plurality of electromagnetic radiations 16 are attenuated by the target object 18 and at least some of attenuated electromagnetic radiations 20 impacts the imaging detector 22, for example, a fluoroscopic detector.

The imaging detector 22 may operate based on scintillation, i.e., optical conversion, direct conversion, or other techniques used for generation of electrical signals based on the incident electromagnetic radiations 20. For example, a scintillator-based imaging detector converts incident photons to optical photons. Such optical photons are then converted to electrical signals by employing photosensor(s), such as, for example, photodiode(s). If a direct conversion imaging detector is used, such a detector directly generates electrical charges in response to incident photons. The electrical charges can be stored and read out from storage capacitors. As described in detail below, electrical signals, regardless of the conversion technique employed, are acquired and processed to construct an image of the features (e.g., anatomy) of the target object 18.

Circuitry 24 is coupled to a source 12 and configured to provide electric power and control signals to the source 12. The imaging detector 22 is coupled to acquisition circuitry 26 configured to receive electrical readout signals generated by the imaging detector 22. The acquisition circuitry 26 may be further configured to execute various signal processing and filtration functions, such as, for example, initial adjustment of dynamic ranges to regulate an amount of radiations for imaging, digitally combining spatially shifted sub-images to construct a high-resolution composite image of the target, and so forth.

The circuitry 24 and the acquisition circuitry 26 are coupled to a system controller 28. The system controller 28 is configured to generate control signals for controlling the circuitry 24. In some embodiments, the system controller 28 can include signal processing circuitry, typically based upon a general purpose or application specific digital computer programmed to process signals based on one or more parameters of processing, such as for example, a ratio of pulse height of the signal to the energy of the electromagnetic rays incident on the imaging detector 22. The system controller 28 may also include memory circuitry for storing programs and routines executed by the computer, configuration parameters, image data, interface circuits, and so forth.

Image processing circuitry 30 is coupled to the acquisition circuitry 26 and configured to receive acquired projection data from the acquisition circuitry 26. The image processing circuitry 30 is configured to process the acquired projection data to generate one or more images of the target object 18 based on attenuation of photons.

A workstation 32 is communicatively coupled to the system controller 28 and the image processing circuitry 30 to initiate and configure imaging of the target object 18 and to view or print images generated from photons that impinge the imaging detector 22. For example, an operator may provide instructions or commands to the system controller 28 via one or more input devices associated with the workstation 32. The workstation 32 can receive and display or print an output of the image processing circuitry 30, using an output device 34 such as a display or printer. The output device 34 may include a standard or special purpose computer monitor and an associated processing circuitry. In some embodiments, at least one of the system controller 28, the image processing circuitry 30, and workstation 32 may be embodied in a single processor-based computing system.

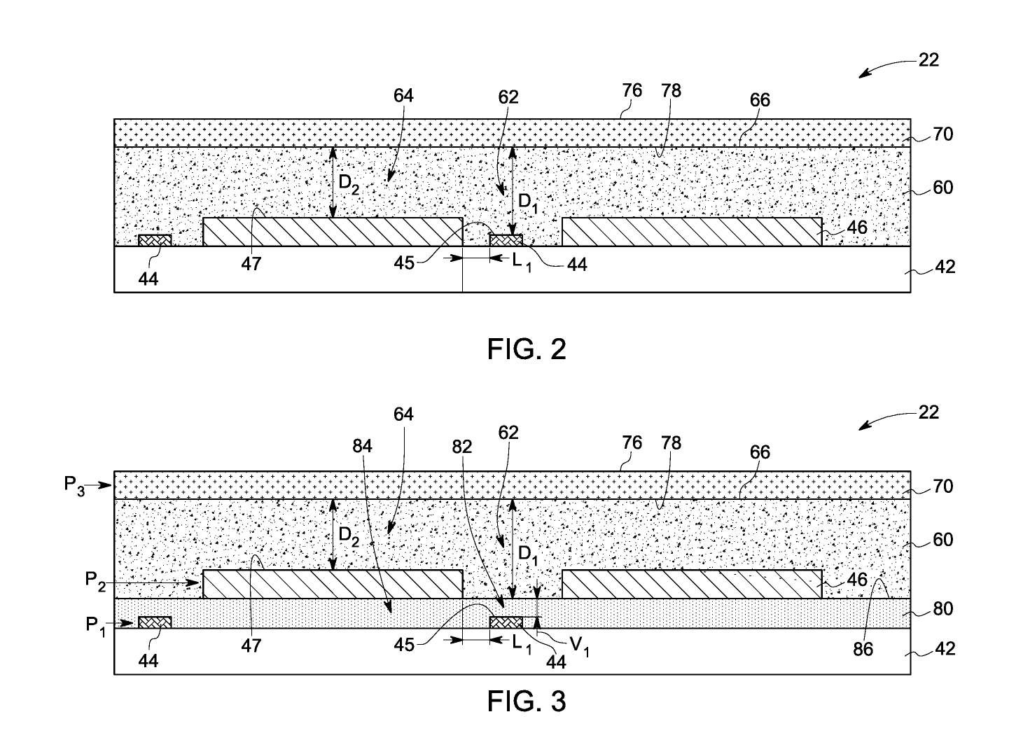

FIG. 2 shows a side cross-sectional view of a portion of an exemplary imaging detector 22 depicted in FIG. 1. The imaging detector 22 includes data lines 44 disposed on a rigid or flexible substrate 42. The data lines 44 are disposed on the substrate 42. Pixelated bottom electrodes 46 are disposed on the substrate 42 such that the pixelated bottom electrodes 46 are laterally offset from the data lines 44. A continuous organic photodiode layer 60 is disposed on the substrate 42 overlaying the pixelated bottom electrodes 46 and the data lines 44. A continuous top electrode layer 70 is overlaid on the continuous organic photodiode layer 60. In some embodiments, the continuous organic photodiode layer 60 and the continuous top electrode layer 70 are unpatterned continuous layers having a unitary structure. The continuous top electrode layer 70 is coated on a top surface 66 of the continuous organic photodiode layer 60. The continuous organic photodiode layer 60 includes first portions 62 overlaid on the data lines 44 and second portions 64 overlaid on the pixelated bottom electrodes 46. A thickness D₁ of the first portions 62 of the continuous organic photodiode layer 60 is greater than a thickness D₂ of the second portions 64 of the continuous organic photodiode layer 60. In some embodiments, the continuous top electrode layer 70 is overlaid on the top surface 66 of the continuous organic photodiode layer 60 and has a top surface 76 and a bottom surface 78.

FIG. 3 shows a side cross-sectional view of a portion of another exemplary imaging detector 22. The imaging detector 22 includes data lines 44 disposed on a rigid or flexible substrate 42. The data lines 44 are disposed on a plane P₁ on the substrate 42. A passivation (dielectric) layer 80 is disposed on the substrate 42, overlaying the data lines 44. The passivation layer may include inorganic materials and/or organic materials. In some embodiments, the inorganic materials may include oxides or nitrides such as, for example, silicon dioxide and/or silicon nitride. A non-limiting example of an organic material may include an acrylate.

Pixelated bottom electrodes 46 are disposed on plane P₂ on the passivation layer 80 such that the pixelated bottom electrodes 46 are laterally offset from the data lines 44. A continuous organic photodiode layer 60 is disposed on the passivation layer 80, overlaying the pixelated bottom electrodes 46 and a continuous top electrode layer 70 is overlaid on the continuous organic photodiode layer 60. The passivation layer 80 includes first portions 82 that are in direct contact with the data lines 44 and first portions 62 of the continuous organic photodiode layer 60. The passivation layer 80 further includes second portions 84 that are in direct contact with the substrate 42 and the pixelated bottom electrodes 46.

The pixelated bottom electrodes 46 are disposed on the substrate 42 as shown in FIG. 2 or on passivation layer 80 as shown in FIG. 3, laterally offset from the data lines 44. In the illustrated embodiment, the lateral offset between the data lines 44 and the pixelated bottom electrodes 46 is represented by L₁. Further, the pixelated bottom electrodes 46 are also vertically offset from the data lines 44. A vertical offset between a top surface 45 of the data lines 44 and a bottom surface of the pixelated bottom electrode 46 is represented by V₁. In some embodiments, the pixelated bottom electrodes 46 are vertically offset from the data lines 44 by a thickness value of the passivation layer 80.

The continuous organic photodiode layer 60 includes the first portions 62 overlaid on the data line 44 (FIG. 2) or on the passivation layer 80 (FIG. 3) and second portions 64 overlaid on the pixelated bottom electrodes 46. A thickness D₁ of the first portions 62 is greater than a thickness D₂ of the second portions 64 of the continuous organic photodiode layer 60. The continuous top electrode layer 70 is disposed over the continuous organic photodiode layer 60. Specifically, the thickness D₁ of the first portions 62 of the continuous organic photodiode layer 60 is defined between a bottom surface 78 of the continuous top electrode layer 70 and a top surface 45 of the data line 44 or a top surface 86 of the passivation layer 80. The thickness D₂ of the second portions 64 of the continuous organic photodiode layer 60 is defined between the bottom surface 78 of the continuous top electrode layer 70 and a top surface 47 of the pixelated bottom electrodes 46. The thickness D₁ of the first portions 62 being different from the thickness D₂ of the second portions 64 facilitates to control electronic noise of the imaging detector 22 during operation. In some embodiments, the continuous organic photodiode layer 60 is formed by wet-coating process.

In some embodiments, the thickness D₁ of the first portions 62 is at least 50 nanometers greater than the thickness D₂ of the second portions 64 of the continuous organic photodiode layer 60. In certain embodiments, the thickness D₁ of the first portions 62 of the continuous organic photodiode layer 60 is at least 500 nanometers. In certain other embodiments, the thickness D₁ of the first portions 62 of the continuous organic photodiode layer 60 is at least one micrometer (1μ).

The lateral offset L₁ between the pixelated bottom electrodes 46 and the data lines 44 facilitates to control an indirect capacitive coupling between the pixelated bottom electrodes 46 and the data lines 44. In some embodiments, the lateral offset L₁ is greater than 1μ. In some other embodiments, the lateral offset L₁ can be greater than one and a half microns (1.5μ). If the lateral offset L₁ is greater, the indirect capacitive coupling between the pixelated bottom electrodes 46 and the data lines 44 is reduced. The number of data lines 44 and the pixelated bottom electrodes 46 may vary depending on the application.

The continuous organic photodiode layer 60 can be printed or formed in stripes over the pixelated bottom electrodes 46, data lines 44, and on the substrate 42 as in FIG. 2 or over the pixelated bottom electrodes 46 and passivation layer 80 as shown in FIG. 3. In some embodiments, the continuous organic photodiode layer 60 can be formed by low cost ink-jet patterning or other direct write techniques. It should be noted herein that the vertical distance between the top surface 45 of the data lines 44 and the bottom surface 78 of the continuous top electrode layer 70 influences parasitic capacitance that increases electronic noise of the imaging detector 22. This distance is denoted by D₁ in FIG. 2 and defined by D₁+V₁ in FIG. 3. An increase in the vertical distance facilitates to decrease electronic noise arising due to capacitive coupling between the data lines 44 and the continuous top electrode layer 70.

In the illustrated embodiment, the continuous top electrode layer 70 has a uniform thickness along plane P₃. The continuous organic photodiode layer 60 has a substantially planar top surface 66 contacting the continuous top electrode layer 70. The continuous top electrode layer 70 also includes a substantially planar top surface 76, as shown in FIG. 2 and FIG. 3.

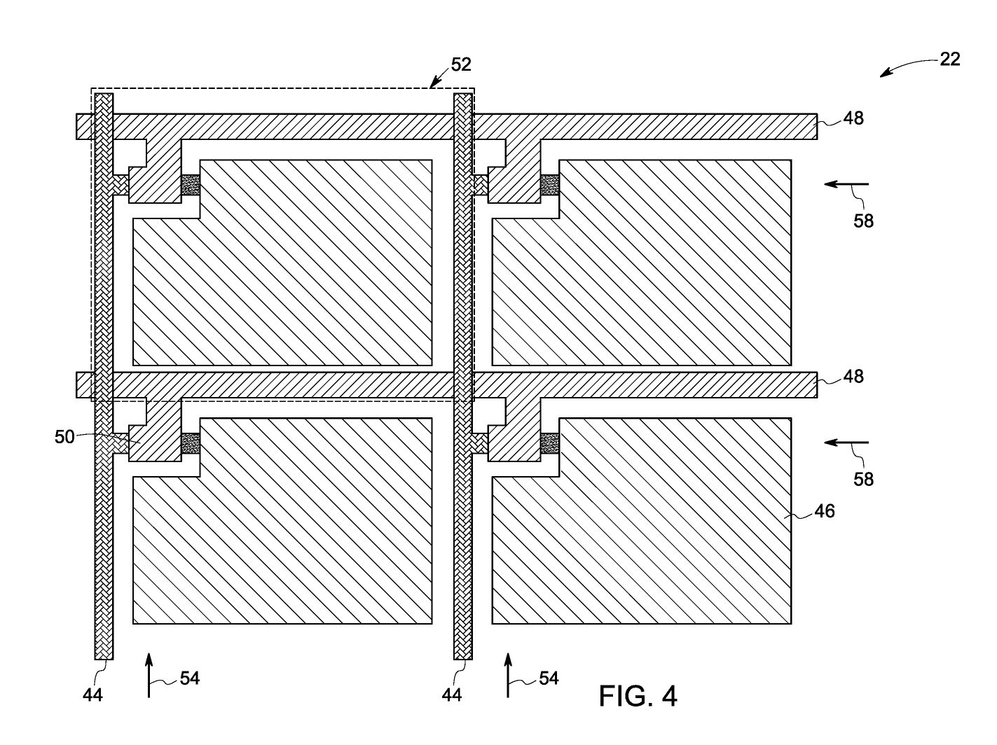

FIG. 4 shows a sectional view of the imaging detector 22 in accordance with an exemplary embodiment of the present invention. The imaging detector includes the data lines 44, pixelated bottom electrodes 46, scan lines 48, and a plurality of TFTs 50. The data lines 44, the pixelated bottom electrodes 46, and the scan lines 48 may be composed of metallic, dielectric, organic, and/or inorganic materials. Such layers may be formed by deposition techniques including, for example, chemical vapor deposition, physical vapor deposition, electrochemical deposition, stamping, printing, sputtering, and/or any other suitable deposition techniques.

The plurality of TFTs 50 are passive or active pixels, which store charge for read out by electronics unit, disposed on an active layer formed of amorphous silicon or amorphous metal oxides, or organic semiconductors. In some embodiments, the plurality of TFTs 50 include a plurality of silicon TFTs, a plurality of oxide TFTs, a plurality of organic TFTs, or combinations thereof. Suitable amorphous metal oxides include zinc oxide, zinc tin oxide, indium oxides, indium zinc oxides (In—Zn—O series), indium gallium oxides, gallium zinc oxides, indium silicon zinc oxides, and indium gallium zinc oxides (IGZO). IGZO materials include InGaO₃(ZnO)ₘ where m is <6 and InGaZnO₄. Suitable organic semiconductors include, but are not limited to, conjugated aromatic materials, such as rubrene, tetracene, pentacene, perylenediimides, tetracyanoquinodimethane and polymeric materials such as polythiophenes, polybenzodithiophenes, polyfluorene, polydiacetylene, poly(2,5-thiophenylene vinylene), poly(p-phenylene vinylene) and derivatives thereof.

The imaging detector 40 includes an array of pixels 52. Each pixel 52 includes at least one TFT 50 operatively coupled to at least one of the data lines 44, at least one of the scan lines 48, and to at least one pixelated bottom electrode 46. In some embodiments, the TFTs 50 are arranged in the form of a two-dimensional array having rows 54 and columns 58. In such embodiments, the imaging detector 22 includes an array of pixelated bottom electrodes 46 and plurality of data lines 44.

In some other embodiments, the TFTs 50 can be arranged in other configurations. For example, the TFTs can be arranged in a honeycomb pattern. The spatial density of the TFTs 50 is defined based on a quantity of the pixels 52 in the array, physical dimensions of the pixel array, pixel density or resolution of the imaging detector 22.

Each data line 44 is in electrical communication with an output of at least one of the TFTs 50. For example, each data line 44 is associated with a row 54 or a column 58 of the TFTs 50. An output (e.g., source or drain) of each TFT 50 in the corresponding row or column is in electrical communication with the corresponding data line 44. The data lines 44 are susceptible to interferences such as electronic noise generated from a surrounding environment. Such interferences can affect data signals transmitted along the data lines 44. Electronic noise may also be introduced on the data lines 44 due to capacitive coupling of conductive components in the imaging detector 22. The data lines 44 may be formed of a conductive material, such as a metal, and configured to facilitate transmission of electrical signals, corresponding to incident photons, to the image processing circuitry.

The scan lines 48 are in electrical communication with inputs (e.g., gates) of the TFTs 50. For example, each scan line 48 is associated with a column 58 or row 54 of the TFTs 50. The input of each TFT 50 in the corresponding row or column is in electrical communication with the corresponding scan line 48. Electrical signals transmitted along the scan lines 48 are used to control the TFTs 50 to output data such that the data flows through the corresponding data lines 44. In certain exemplary embodiments, the scan lines 48 and the data lines 44 may extend perpendicularly to each other to form a grid. The scan lines 48 may be formed of a conductive material, such as a metal, and configured to facilitate transmission of electrical signals from the system controller to the inputs of the TFTs 50.

The pixelated bottom electrodes 46 are deposited on the substrate 42 or on the passivation layer 80 and provide electrical contact between the continuous organic photodiode layer 60 and the TFTs 50 of the imaging detector 22. In some embodiments, the pixelated bottom electrodes 46 and the continuous top electrode layer 70 form anodes and cathode, respectively, or vice versa. Suitable anode materials include, but are not limited to, metals such as aluminum, silver, gold, platinummetal oxides such as ITO, IZO, and ZO, and organic conductors such as p-doped conjugated polymers like PEDOT. Suitable cathode materials include transparent conductive oxides (TCO) and thin films of metals such as gold and silver. Examples of suitable TCO include ITO, IZO, AZO, FTO, SnO₂, TiO₂, ZnO, indium zinc oxides (In—Zn—O series), indium gallum oxides, gallium zinc oxides, indium silicon zinc oxides, and IGZO. In many embodiments, ITO is used because of low resistance and transparency. The anodes and cathodes may be disposed using various methods, such as, for example, by sputtering or patterned using photolithography.

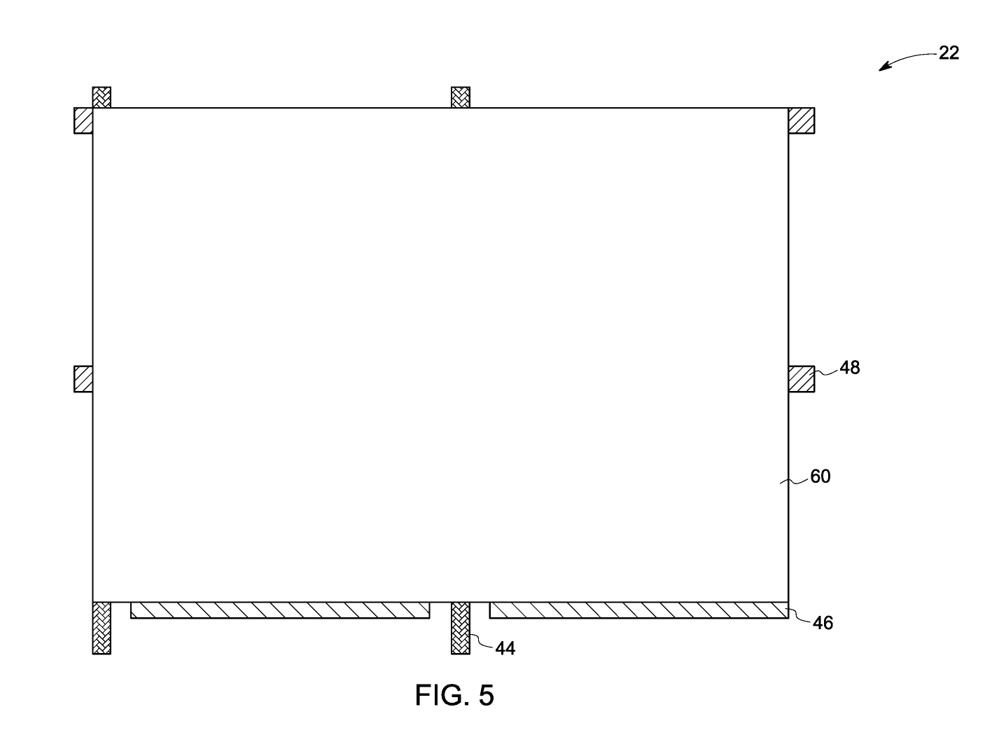

FIG. 5 shows a cross sectional view of the imaging detector 22 in accordance with an exemplary embodiment. The continuous organic photodiode layer 60 is at least partially deposited over the TFTs, the data lines 44, the scan lines 48, and the pixelated bottom electrodes 46.

The continuous organic photodiode layer 60 may be formed of one or more organic photoelectric materials that convert photons to electric current. The continuous organic photodiode layer 60 may be composed of at least a donor material and an acceptor material; where the donor material includes at least one low bandgap polymer. The continuous organic photodiode layer 60 is a continuous, unpatterned bulk hetero-junction organic photodiode layer that absorbs light, separates charge, and transports holes and electrons to the electrodes. The continuous organic photodiode layer 60 may be composed of a blend of a donor material and an acceptor material; where more than one donor or acceptor may be included in the blend. In some embodiments, the donor and acceptor may be incorporated in a same molecule. The low band gap polymers are conjugated polymers and copolymers composed of units derived from substituted or unsubstituted monoheterocyclic and polyheterocyclic monomers such as thiophene, fluorene, phenylenvinylene, carbazole, pyrrolopyrrole, and fused heteropolycyclic monomers including the thiophene ring, including, but not limited to, thienothiophene, benzodithiophene, benzothiadiazole, pyrrolothiophene monomers, and substituted analogs thereof. In particular embodiments, the low band gap polymers include units derived from substituted or unsubstituted thienothiophene, benzodithiophene, benzothiadiazole, carbazole, isothianaphthene, pyrrole, benzo-bis(thiadiazole), thienopyrazine, fluorene, thiadiazolequinoxaline, or combinations thereof. Examples of suitable materials for use as low bandgap polymers in the organic x-ray detectors include copolymers derived from substituted or unsubstituted thienothiophene, benzodithiophene, benzothiadiazole or carbazole monomers, and combinations thereof, such as poly[[4,8-bis[(2-ethyl hexyl)oxy]benzo[1,2-b:4,5-b]dithiophene-2,6-diyl][3-fluoro-2-[(2-ethylhexyl)carbonyl] thieno[3,4-b]thiophenediyl (PTB7), 2,1,3-benzothiadiazole-4,7-diyl[4,4-bis(2-ethylhexyl)-4H-cyclopenta[2,1-b:3,4-b′]dithiophene-2,6-diyl (PCPDTBT), poly[[9-(1-octylnonyl)-9H-carbazole-2,7-diyl]-2,5-thiophenediyl-2,1,3-benzothiadiazole-4,7-diyl-2,5-thiophenediyl] (PCDTBT), poly[(4,40-bis(2-ethylhexyl)dithieno[3,2-b: 20,30-d]silole)-2,6-diyl-alt-(2,1,3-benzo-thiadiazole)-4,7-diyl] (PSBTBT), poly((4,8-bis(octyloxy)benzo(1,2-b:4,5-b′)dithiophene-2,6-diyl)(2-((dodecyloxy)carbonyl) thieno(3,4-b)thiophenediyl)) (PTB1), poly((4,8-bis(octyloxy)benzo(1,2-b:4,5-b′)dithiophene-2,6-diyl)(2-((ethylhexyloxy)carbonyl) thieno(3,4-b)thiophenediyl)) (PTB2), poly((4,8-bis(octyl)benzo(1,2-b:4,5-b′)dithiophene-2,6-diyl) (2-((ethylhexyloxy)carbonyl) thieno(3,4-b)thiophenediyl)) (PTB3), poly((4,8-bis-(ethylhexyloxybenzo(1,2-b:4,5-b′)dithiophene-2,6-diyl)(2-((octyloxy)carbonyl)-3-fluoro)thieno(3,4-b)thiophenediyl)) (PTB4), poly((4,8-bis(ethylhexyloxybenzo(1,2-b:4,5-b′)dithiophene-2,6-diyl)(2-((octyloxy)carbonyl) thieno (3,4-b)thiophenediyl)) (PTB5), poly((4,8-bis(octyloxy)benzo(1,2-b:4,5-b′)dithiophene-2,6-diyl)(2-((butyloctyloxy)carbonyl) thieno(3,4-b)thiophenediyl)) (PTB6), poly[[5-(2-ethylhexyl)-5,6-dihydro-4,6-dioxo-4H-thieno[3,4-c]pyrrole-1,3-diyl][4,8-bis[(2-ethylhexyl)oxy]benzo[1,2-b:4,5-b′]dithiophene-2,6-diyl]] (PBDTTPD), poly[1-(6-{4,8-bis[(2-ethylhexyl)oxy]-6-methylbenzo[1,2-b:4,5-b]dithiophen-2-yl}-3-fluoro-4-methylthieno[3,4-b]thiophen-2-yl)-1-octanone] (PBDTTT-CF), and poly[2,1,3-benzothiadiazole-4,7-diyl-2,5-thiophenediyl (9,9-dioctyl-9H-9-silafluorene-2,7-diyl)-2,5-thiophenediyl] (PSiF-DBT). Other suitable materials are poly[5,7-bis (4-decanyl-2-thienyl) thieno[3,4-b]diathiazole-thiophene-2,5] (PDDTT), poly[2,3-bis(4-(2-ethylhexyloxy)phenyl)-5,7-di(thiophen-2-yl)thieno[3,4-b]pyrazine] (PDTTP), and polythieno[3,4-b]thiophene (PTT). In particular embodiments, suitable materials are copolymers derived from substituted or unsubstituted benzodithiophene monomers, such as the PTB1-7 series and PCPDTBT; or benzothiadiazole monomers, such as PCDTBT and PCPDTBT. In particular embodiments, the donor material is a polymer with a low degree of crystallinity or is an amorphous polymer. Degree of crystallinity may be increased by substituting aromatic rings of the main polymer chain. Long chain alkyl groups containing six or more carbons or bulky polyhedral oligosilsesquioxane (POSS) may result in a polymer material with a lower degree of crystallinity than a polymer having no substituents on the aromatic ring, or having short chain substituents such as methyl groups. Degree of crystallinity may also be influenced by processing conditions and means, including, but not limited to, the solvents used to process the material and thermal annealing conditions. Degree of crystallinity is readily determined using analytical techniques such as calorimetry, differential scanning calorimetry, x-ray diffraction, infrared spectroscopy and polarized light microscopy.

Suitable materials for the acceptor include fullerene derivatives such as [6,6]-phenyl-C₆₁-butyric acid methyl ester (PCBM), PCBM analogs such as PC₇₀BM, PC₇₁BM, PC₈₀BM, bis-adducts thereof, such as bis-PC₇₁BM, indene mono-adducts thereof, such as indene-C₆₀ monoadduct (ICMA) and indene bis-adducts thereof, such as indene-C₆₀ bisadduct (ICBA). Fluorene copolymers such as poly[(9,9-dioctylfluorenyl-2,7-diyl)-alt-(4,7-bis(3-hexylthiophen-5-yl)-2,1,3-benzothiadiazole)-2′,2″-diyl] (F8TBT) may also be used, alone or with a fullerene derivative.

In some embodiments, the photoelectric material is formed continuously as a unitary structure on the array of TFTs, the data lines 44, the scan lines 48 and substantially over the pixelated bottom electrodes 46. In some embodiments, the continuous organic photodiode layer 60 is deposited over the entire area of the pixelated bottom electrodes 46 and the TFTs 50. As a result, the pixel density of the imaging detector can be increased compared to conventional imaging detectors.

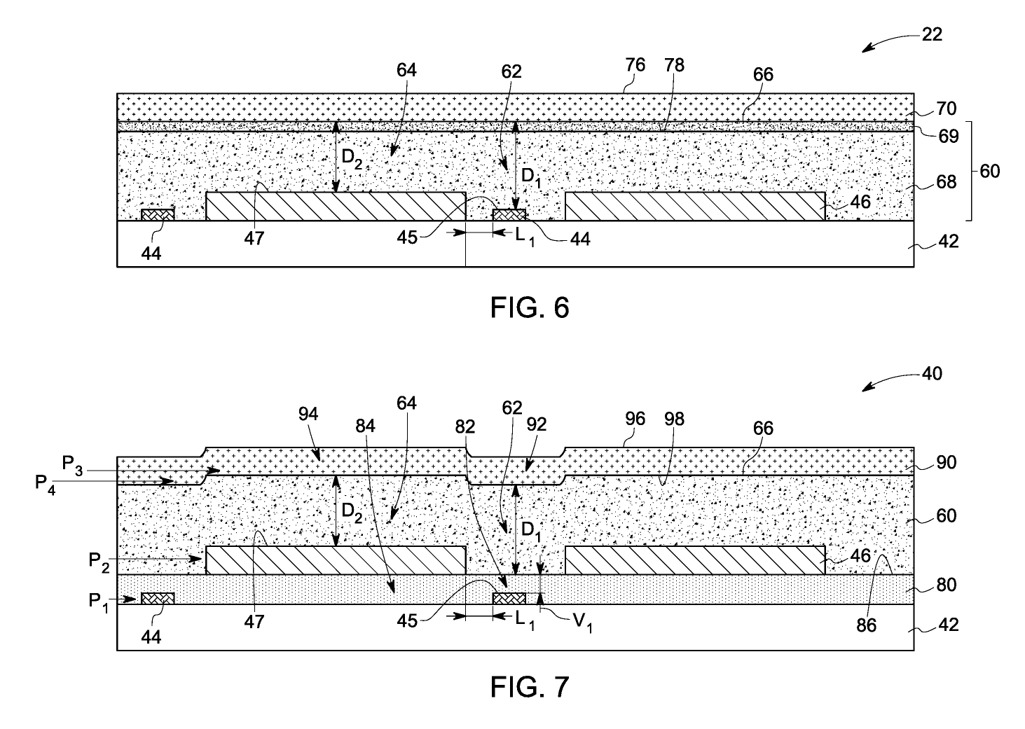

FIG. 6 is a side cross-sectional view of the imaging detector in accordance with some embodiments of the present invention. The continuous organic photodiode layer 60 includes a continuous organic photoelectric layer 68 and a continuous charge blocking layer 69. The charge blocking layer 69 is configured to suppress injection of a charge from the pixelated bottom electrodes 46 or the continuous top electrode layer 70 to the continuous organic photodiode layer 60 upon application of a voltage. In some embodiments, the charge blocking layer 69 is an electron blocking layer configured to block electrons and transport holes. The electron blocking layer may include, but not limited to, aromatic tertiary amines and polymeric aromatic tertiary amines. Non-limiting examples of suitable materials include poly-TPD (poly(4-butylphenyl-diphenyl-amine), poly(N,N′-bis(4-butylphenyl)-N,N′-bis(phenyl) benzidine, 4,4′,N,N′-diphenylcarbazole, 1,3,5-tris(3-methyldiphenyl-amino)benzene, N,N′-bis(1-naphtalenyl)-N—N′-bis(phenylbenzidine), N,N′-Bis-(3-methylphenyl)-N,N′-bis(phenyl) benzidine, N,N′-bis(2-naphtalenyl)-N—N′-bis-(phenylbenzidine), 4,4′,4″-tris(N,N-phenyl-3-methylphenylamino)triphenylamine, poly[9,9-dioctylfluorenyl-2,7-dyil)-co-(N,N′bis-(4-butylphenyl-1,1′-biphenylene-4,4-diamine)], poly(N,N′-bis(4-butylphenyl)-N,N′-bis(phenyl)benzidine, poly[(9,9-dihexylfluorenyl-2,7-diyl)-co-(N,N′bis{p-butylphenyl}-1,4-diamino-phenylene)], NiO, MoO3, tri-p-tolylamine, 4,4′,4″-tris[phenyl(m-tolyl)amino]triphenylamine, 4,4′,4″-tris[2-naphthyl(phenyl)amino] triphenylamine, 1,3,5-tris[(3-methylphenyl)phenylamino] benzene, 1,3,5-tris(2-(9-ethylcabazyl-3)ethylene)benzene, 1,3,5-tris(diphenylamino) benzene, tris[4-(diethylamino)phenyl]amine, tris(4-carbazoyl-9-ylphenyl)amine, titanyl phthalocyanine, tin(IV) 2,3-naphthalocyanine dichloride, N,N,N′,N′-tetraphenyl-naphthalene-2,6-diamine, tetra-N-phenylbenzidine, N,N,N′,N′-tetrakis(2-naphthyl) benzidine, N,N,N′,N′-tetrakis(3-methylphenyl)-3,3′-dimethylbenzidine, N,N,N′,N′-tetrakis(4-methoxyphenyl)benzidine, poly(2-vinylnaphthalene), poly(2-vinylcarbazole), poly(N-ethyl-2-vinylcarbazole), poly(copper phthalocyanine), poly[bis(4-phenyl)(2,4,6-trimethylphenyl)amine], dipyrazino[2,3-f:2′,3′-h]quinoxaline-2,3,6,7,10,11-hexacarbonitrile 99%, N,N′-diphenyl-N,N′-di-p-tolylbenzene-1,4-diamine, 4-(diphenylamino)benzaldehyde diphenylhydrazone, N,N′-di(2-naphthyl-N,N′-diphenyl)-1,1′-biphenyl-4,4′-diamine, 9,9-dimethyl-N,N′-di(1-naphthyl)-N,N′-diphenyl-9H-fluorene-2,7-diamine, 2,2′-dimethyl-N,N′-di-[(1-naphthyl)-N,N′-diphenyl]-1,1′-biphenyl-4,4′-diamine, 4-(dibenzylamino)benzaldehyde-N,N-diphenyl-hydrazone, 4,4′-Cyclohexylidenebis[N,N-bis(4-methylphenyl)benzenamine], N,N′-Bis(phenanthren-9-yl)-N,N′-bis(phenyl)-benzidine, N,N′-Bis(3-methylphenyl)-N,N′-diphenylbenzidine, 4,4′-Bis(3-ethyl-N-carbazolyl)-1,1′-biphenyl, 1,4-Bis(diphenylamino)benzene, 4,4′-Bis(N-carbazolyl)-1,1′-biphenyl, 4,4′-Bis(N-carbazolyl)-1,1′-biphenyl, and 1,3-Bis(N-carbazolyl)benzene.

In certain embodiments, the charge blocking layer 69 is a hole blocking layer configured to blocking holes and transport electrons. Suitable materials for the hole blocking layer include phenanthroline compounds, for example, 2,9-dimethyl-4,7-diphenyl-1,10-phenanthroline (BCP), 4-biphenyloxolate aluminum(III) bis(2-methyl-8-quinolinato)-4-phenylphenolate (BAlq), 2,4-diphenyl-6-(49-triphenylsilanyl-biphenyl-4-yl)-1,3,5-triazine (DTBT), C60, (4,4′-N,N′-dicarbazole)biphenyl (CBP), as well as a range of metal oxides, such as TiO₂, ZnO, Ta₂O₅, and ZrO₂. In some embodiments, the charge blocking layer 69 is disposed between the organic photoelectric layer 68 and the continuous top electrode layer 70. In some embodiments, the charge blocking layer 69 includes metal fluorides. The metal fluoride may be lithium fluoride, sodium fluoride, potassium fluoride, rubidium fluoride, cesium fluoride, beryllium fluoride, magnesium fluoride, calcium fluoride, strontium fluoride, barium fluoride, iron fluoride, yttrium fluoride, ytterbium fluoride, or a combination thereof. In certain embodiments, the charge blocking layer is substantially free of an electrically conductive material and the thickness is greater than about 10 nanometers.

FIG. 7 shows a side cross-sectional view of a portion of an exemplary imaging detector 40 in accordance with another exemplary embodiment. The illustrated embodiment is similar to the embodiment of FIG. 3 except that a continuous top electrode layer 90 has a first portion 92 extending along a plane P₄ and a second portion 94 extending along a plane P₃ which is above plane P₄. The continuous electrode layer 90 is deposited over the top surface 66 of the continuous organic electrode layer 60 and has a tope surface 96 and a bottom surface 98. The vertical distance (e.g. D₁+V₁) between the top surface 45 of the data lines 44 and the bottom surface 98 of the continuous top electrode layer 70 in the plane P₄ influences parasitic capacitance that increases electronic noise of the imaging detector 22.

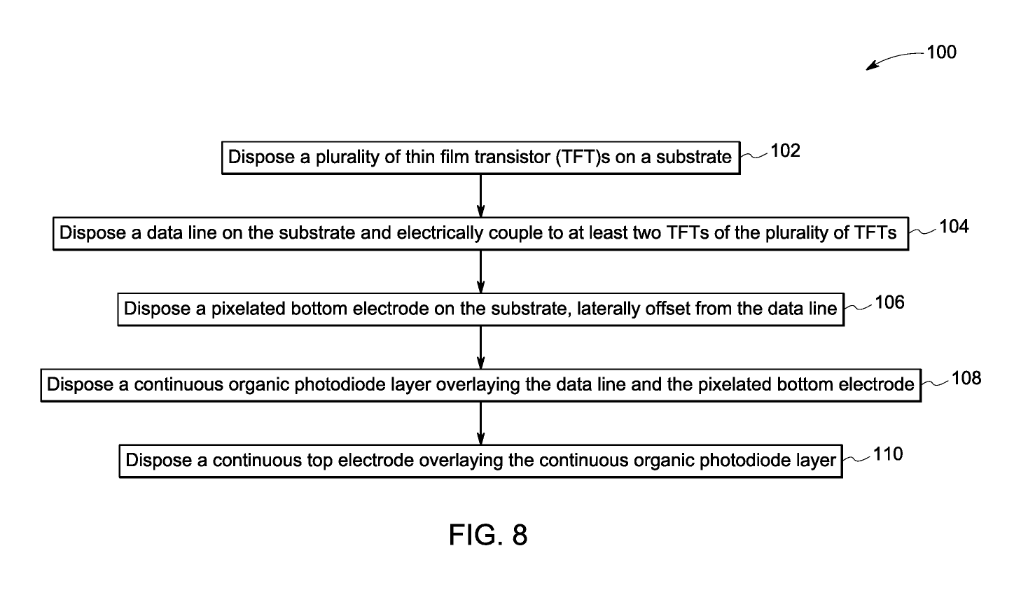

FIG. 8 is a flowchart 100 of an exemplary process for manufacturing an imaging detector in accordance with an exemplary. At step 102, a plurality of thin film TFT (TFT)s is disposed on a substrate. At step 104, data lines are disposed on the substrate and electrically coupled to at least two TFTs of the plurality of TFTs. In some embodiments, the plurality of TFTs are arranged along a plurality of rows and columns to form an array. In certain embodiments, a corresponding data line extends along one of the columns and is connected to an output of each TFT of the corresponding column.

At step 106, pixelated bottom electrodes are disposed on the substrate, laterally offset from the data lines. In some embodiments, a passivation layer is disposed on the substrate, overlaying the data lines, and then the pixelated bottom electrodes are formed on the passivation layer. Passivation layer having inorganic materials may be applied by physical vapor deposition, chemical vapor deposition or sputtering processes. Passivation layer having organic materials may be disposed by wet coating techniques such as, for example, slot die, ink jet, and/or spray coating.

The pixelated bottom electrodes are in electrical communication with one of the TFTs in the array. At step 108, a continuous organic photodiode layer is disposed at least partially overlaying the plurality of TFTs, the data lines, and the pixelated bottom electrodes. The continuous organic photodiode layer is disposed such that a thickness of a first portion of the continuous organic photodiode layer overlaying the data lines is greater than a thickness of a second portion of the continuous organic photodiode layer overlaying the pixelated bottom electrodes. At step 110, a continuous top electrode layer is disposed overlaying the continuous organic photodiode layer. Further, the imaging detector may further include one or more top layers over the continuous top electrode layer, such as, for example, planarization layers.

In some embodiments, the continuous organic photodiode layer is formed by a solution deposition method. In some embodiments, the continuous organic photodiode layer may be coated on the substrate (or the passivation layer 80), the data lines, and the pixelated bottom electrodes using a solution deposition method such as, for example, a metal-organic thin-film deposition method. The continuous top electrode layer may be sputter deposited on a surface of the continuous organic photodiode layer.

In describing various embodiments, specific terminology is used for the sake of clarity. For purposes of description, each specific term is intended to at least include all technical and functional equivalents that operate in a similar manner to accomplish a similar purpose. Additionally, in some instances where particular embodiments include a plurality of system elements, device components or method steps, those elements, components or steps may be replaced with a single element, component or step. Likewise, a single element, component or step may be replaced with a plurality of elements, components or steps that serve the same purpose. Moreover, while some features have been shown and described with references to embodiments thereof, those of ordinary skill in the art will understand that various substitutions and alterations in form and detail may be made therein without departing from the scope of the invention. Further still, other aspects, functions and advantages are also within the scope of the invention.

1. An imaging detector comprising:
a substrate;
a plurality of thin film transistors (TFTs) disposed on the substrate;
a data line disposed on the substrate and electrically coupled to at least two TFTs of the plurality of TFTs;
a pixelated bottom electrode disposed on the substrate and laterally offset from the data line;
a continuous organic photodiode layer at least partially overlaid on the plurality of TFTs, the data line, and the pixelated bottom electrode, wherein the continuous organic photodiode layer comprises a first portion overlaid on the data line and a second portion overlaid on the pixelated bottom electrode, and wherein a thickness of the first portion is greater than a thickness of the second portion; and
a continuous top electrode layer overlaid on the continuous organic photodiode layer.

2. The imaging detector of claim 1, wherein the thickness of the first portion and the thickness of the second portion are configured to control electronic noise of the imaging detector during operation.

3. The imaging detector of claim 1, wherein the thickness of the first portion is at least 50 nanometers greater than the thickness of the second portion.

4. The imaging detector of claim 1, wherein the thickness of the first portion is at least 500 nanometers.

5. The imaging detector of claim 1, wherein the thickness of the first portion is at least 1 micrometer.

6. The imaging detector of claim 1, wherein the pixelated bottom electrode is vertically offset from the data line.

7. The imaging detector of claim 1, further comprising a passivation layer disposed between the substrate and the continuous organic photodiode layer, overlaying the data line.

8. The imaging detector of claim 7, wherein the passivation layer comprises a first portion in direct contact with the data line and the first portion of the continuous organic photodiode layer.

9. The imaging detector of claim 8, wherein the passivation layer further comprises a second portion in direct contact with the substrate and the pixelated bottom electrode.

10. The imaging detector of claim 1, wherein the continuous organic photodiode layer comprises a continuous organic photoelectric layer and a continuous charge blocking layer.

11. The imaging detector of claim 1, wherein the continuous organic photodiode layer comprises a substantially planar top surface contacting the continuous top electrode layer.

12. The imaging detector of claim 1, wherein the continuous top electrode layer comprises a substantially planar top surface.

13. The imaging detector of claim 1, further comprising:
an array of TFTs comprising the plurality of TFTs;
an array of pixelated bottom electrodes comprising the pixelated bottom electrode; and
a plurality of data lines comprising the data line, wherein the array of pixelated bottom electrodes is vertically offset from the plurality of data lines.

14. An imaging system comprising:
a source configured to generate a plurality of electromagnetic radiations,
a collimator disposed aligned with the source and configured to collimate the plurality of electromagnetic radiations, and
an imaging detector disposed aligned with the source and collimator and configured to detect an image of an object through which a collimated electromagnetic radiation is passed through, wherein the imaging detector comprises:
a substrate;
a plurality of thin film transistors (TFTs) disposed on the substrate;
a data line disposed on the substrate and electrically coupled to at least two TFTs of the plurality of TFTs;
a pixelated bottom electrode disposed on the substrate and laterally offset from the data line;
a continuous organic photodiode layer at least partially overlaid on the plurality of TFTs, the data line, and the pixelated bottom electrode, wherein the continuous organic photodiode layer comprises a first portion overlaid on the data line and a second portion overlaid on the pixelated bottom electrode, and wherein a thickness of the first portion is greater than a thickness of the second portion and configured to control electronic noise of the imaging detector during operation; and
a continuous top electrode layer overlaid on the continuous organic photodiode layer.

15. The imaging system of claim 14, wherein the thickness of the first portion is at least 50 nanometers greater than the thickness of the second portion.

16. The imaging system of claim 14, wherein the pixelated bottom electrode is vertically offset from the data line.

17. A method of manufacturing an imaging detector, the method comprising:
disposing a plurality of thin film transistor (TFT)s on a substrate;
disposing a data line on the substrate and electrically coupling the data line to at least two TFTs of the plurality of TFTs;
disposing a pixelated bottom electrode on the substrate, laterally offset from the data line;
disposing a continuous organic photodiode layer at least partially overlaying the plurality of TFTs, the data line, and the pixelated bottom electrode such that the continuous organic photodiode layer comprises a first portion overlying the data line and a second portion overlying the pixelated bottom electrode, wherein a thickness of the first portion is greater than a thickness of the second portion; and
disposing a continuous top electrode layer overlaying the continuous organic photodiode layer.

18. The method of claim 17, wherein disposing the continuous organic photodiode layer comprises forming the continuous organic photodiode layer by a solution deposition method.

19. The method of claim 17, wherein the pixelated bottom electrode is disposed vertically offset from the data line.

20. The method of claim 17, wherein the plurality of TFTs are arranged along a plurality of rows and columns to form an array, and wherein the data line extends along at least one of the plurality of columns and is connected to an output of each of the TFTs of the one column.
